(19) United States
(12) Patent Application Publication
(10) Pub. No.: US 2009/0137119 A1
(43) Pub. Date: May 28, 2009

(54) NOVEL SEAL ISOLATION LINER FOR USE IN CONTACT HOLE FORMATION

(75) Inventors: Hsin-Lun Liu, Taipei (TW); Huan-Just Lin, Hsinchu City (TW); Shih-Chang Chen, Hsin-Chu (TW)

Correspondence Address: DUANE MORRIS LLP (TSMC);IP DEPARTMENT, 30 SOUTH 17TH STREET, PHILADELPHIA, PA, 19103-4196, US

(73) Assignee: Taiwan Semiconductor Manufacturing Co., Ltd., Hsin-Chu (TW)

(21) Appl. No.: 11/946,489

(22) Filed: Nov. 28, 2007

(51) Int. Cl. H01L 21/768

(52) U.S. Cl. 438/675; 257/E21.586

(57) ABSTRACT

A method is disclosed for etching a contact hole in a stack of dielectric layers. The method minimizes bridging defects between the contact hole and adjacent conductive structures. A substrate has a conductive material layer and an active device disposed thereon. An etch stop layer covers the device and the conductive material, A layer of interlevel dielectric and antireflective coating layers are then provided. A hole is etched through the stack using patterned photoresist. Ashing is used to remove all but the etch stop layer and the interlevel dielectric layer. An isolation liner is deposited over the interlevel dielectric layer, the sidewall surfaces of the hole and the exposed upper surface of the etch stop layer. Another etch removes the isolation liner disposed over the exposed upper surface of the etch stop layer, and removes the underlying etch stop layer to expose an upper surface of the conductive material layer.

### FIELD OF THE INVENTION

The disclosure relates to an improved method for forming contact holes, and more particularly to a contact hole formation technique that minimizes poly to contact bridging defects.

### BACKGROUND OF THE INVENTION

As integrated circuits reach ever-higher levels of integration, their shrinking internal dimensions, including both the sizes of circuit elements and the spacing between the circuit elements, pose problems for high-yield fabrication efforts. One problem that can occur is referred to as “bridging,” which results from an unintended and undesired electrical connection between adjacent elements (e.g., metal-filled vias, contacts) that are designed to be electrically isolated. Bridging often occurs as a byproduct of the etching process, in which vias or contact holes are vertically etched in a stack of dielectric material layers. Due to inherent variability in the etching process, such vertical etching can also result in the removal of material laterally (i.e., it can cause etching of the via or contact hole sidewalls). Where adjacent structures are located in close proximity to each other, this lateral etching can result in breakthrough between the structures, or it can result in such a thin dielectric wall between the structures, that an undesired electrical connection (a bridge) is made during device operation.

Such problems can affect fabrication yields by causing unintended conductive connections between adjacent structures, leading to short circuits and device failure.

One method that has been implemented to resolve this bridging problem is to reduce the critical dimension “CD” of the vias or contact holes to thereby increase the thickness of the dielectric material that separates the via/hole from adjacent conductive structure. This method has met with limited success, but is not reliable for cases in which the photomask overlay is shifted.

It would, therefore, be desirable to provide a process for forming contact holes or vias that minimizes or eliminating bridging between the hole/via and adjacent conductive structures.

### SUMMARY OF THE INVENTION

To solve the aforementioned problem, a process is disclosed for providing an isolation liner layer for contact holes and/or vias that reduces or eliminates lateral etching of the hole/via, thereby reducing or eliminating undesired bridging between adjacent conductive circuit elements.

A method of forming a hole in a multi-layer stack is disclosed, comprising the steps of: providing a substrate layer; providing a layer of conductive material over the substrate layer; providing an etch stop layer over said conductive material layer; providing a dielectric layer over the etch stop layer; providing a photoresist layer over the dielectric layer, the photoresist layer have a predetermined pattern; performing a first etch to remove portions of the layers unprotected by the predetermined pattern, thereby forming a hole through the dielectric layer and a portion of the etch stop layer defined by the predetermined pattern; removing the photoresist layer; providing an isolation liner layer over an upper surface of the interlevel dielectric layer, the isolation liner layer further covering inner side surfaces of the hole etched through the interlevel dielectric layer and an upper surface of the etch stop layer exposed by the first etch; and performing a second etch to remove the portion of the isolation liner layer overlying the upper surface of the first dielectric layer exposed by the first etch; wherein the second etch exposes a portion of the conductive material layer.

A method for forming a contact hole or via is further disclosed, comprising the steps of: providing a substrate; providing a layer of conductive material over the substrate; providing a semiconductor device over the conductive material layer; providing a multilayer stack comprising a plurality of dielectric layers; providing a patterned photoresist layer over the multilayer stack; performing a first etch to remove portions of the plurality of layers unprotected by the photoresist layer, the first etch forming a hole through the plurality of layers and ending on or within a first dielectric layer of said multilayer stack, said first dielectric layer directly overlying said conductive material layer; removing the patterned photoresist layer and all but two of the plurality of dielectric layers to leave the first dielectric layer, a second dielectric layer, and the hole formed through the first and second dielectric layers; providing an isolation liner layer over an upper surface of the second dielectric layer, the isolation liner layer further covering inner side surfaces of the hole and an upper surface of the first dielectric layer exposed by the first etch; and performing a second etch to remove the portion of the isolation liner layer overlying the upper surface of the first dielectric layer exposed by the first etch; wherein the second etch exposes a portion of the conductive material layer.

### BRIEF DESCRIPTION OF THE DRAWINGS

These and other features and advantages of the present invention will be more fully disclosed in, or rendered obvious by, the following detailed description of the preferred embodiment of the invention, which is to be considered together with the accompanying drawings wherein like numbers refer to like parts, and further wherein:

FIG. 1 is a cross-section view of a first stage structure during a conventional manufacturing process for forming a contact;

FIG. 2a is a cross-section view of the structure of FIG. 1 subsequent to etching and removal of overlying dielectric and photoresist layers; FIG. 2b is a cross-section view of the structure of FIG. 1 showing bridging of adjacent conductive structures subsequent to etching where the photoresist mask was misaligned;

FIG. 3 is a cross-section view of a portion of a dielectric layer stack in which a contact hole has been etched;

FIG. 4 a cross-section view of the structure of FIG. 3 subsequent to deposition of an exemplary isolation liner layer;

FIG. 5 shows the structure of FIG. 4 subsequent to etching of the isolation liner layer, exposing the underlying contact;

FIG. 6 is a cross-section of a completed contact hole using a conventional process;

FIG. 7 is a cross-section of a completed contact hole formed using the disclosed process, showing the presence of the isolation liner layer and smaller critical dimension of the contact hole than that of the structure of FIG. 6;

FIG. 8 is a flow chart describing the process of manufacturing a contact hole according to the disclosure.

### DETAILED DESCRIPTION

Disclosed herein is a method for etching a contact hole in a stack of dielectric layers where there contact hole is provided with an isolation liner layer prior to a final etching step to minimize or eliminate undesired lateral etching that if unchecked could lead to bridging. The isolation liner layer may comprise any of a number of appropriate materials.

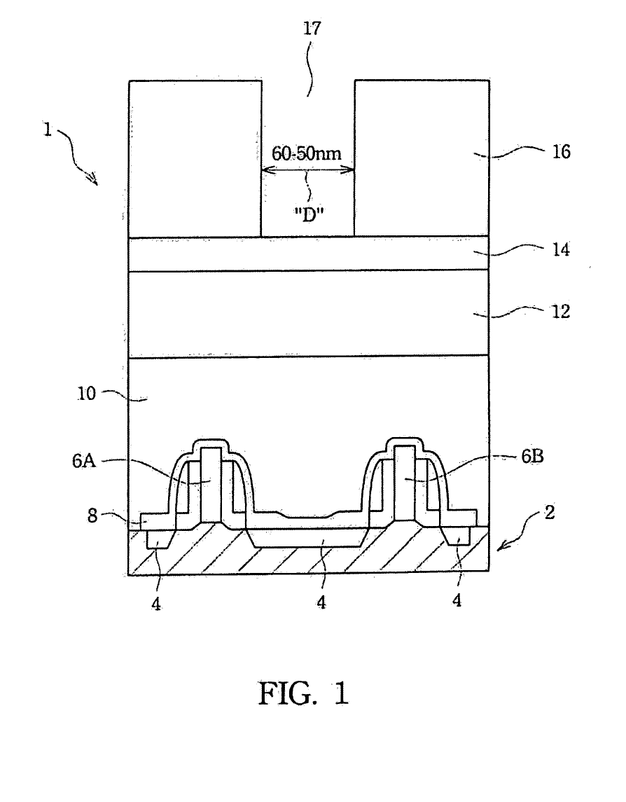

Referring to FIG. 1, stack structure 1 comprises a substrate 2, conductive material layer 4, gate structures 6A, 6B, silicon nitride layer 8, inter-level dielectric layer 10, anti-reflective coating (ARC) layer 12, dielectric anti-reflective coating (DARC) layer 14, and patterned photoresist layer 16. The silicon nitride layer may have a thickness of from about 200 to about 400 Angstroms (Å). The inter-level dielectric layer 10 may have a thickness of about 2000 to about 2500 Å. The ARC layer 12 may have a thickness of about 1500 to about 2000 Å. The DARC layer 14 may have a thickness of about 200 to about 400 Å.

A hole may be formed at a desired location in the stack structure 1 using an anisotropic etching technique, and following a pattern 17 in the photoresist layer 16. In the illustrated embodiment, the pattern 17 is a hole having a cross-sectional dimension “D” of about 50-60 nanometers (nm). Thus, contact hole 18 may be formed through ARC layer 12 and DARC 14 layer using the pattern 17 of photoresist layer 16. Etching may proceed using the silicon nitride layer 8 as an etch stop for the anisotropic etch.

A plasma ashing process may then be used to remove the photoresist layer 16, and the remaining DARC layer 14 and ARC layer 12. A second anisotropic etch may then be performed to remove the portion of the Silicon Nitride layer 8 underlying the previously formed contact hole 18, exposing an upper surface 19 of the conductive material layer 4 to provide a fully formed contact hole 18.

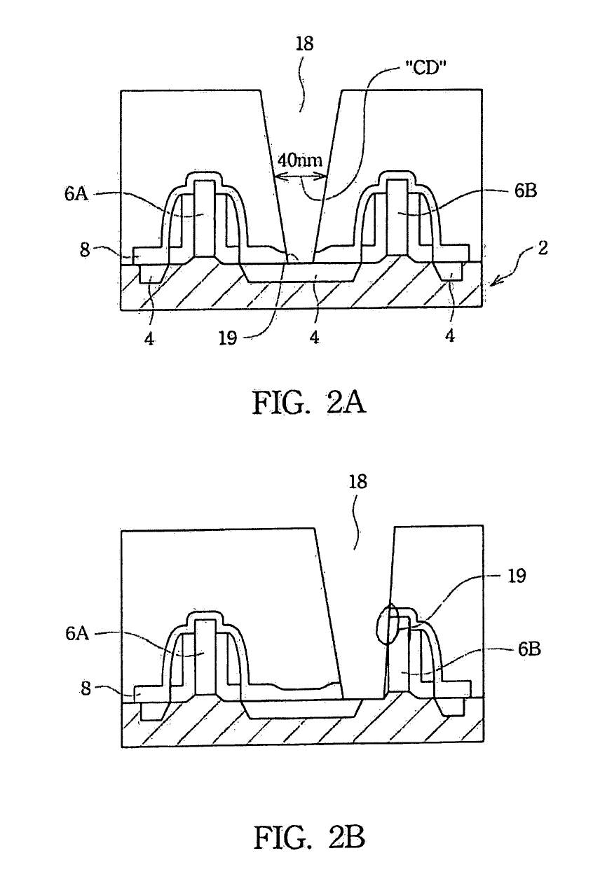

The resulting structure is shown in FIG. 2a. As can be seen, the contact hole 18 may have a generally triangular cross-section that, when viewed in three-dimensions, may have a conical appearance. The contact hole 18 may have a critical dimension “CD” of about 40 nanometers (nm) as measured at approximately the same height as the top of the poly gate 6B, which is the location that has the highest risk of contact-to-poly bridging. It will be appreciated that the CD at the bottom of the hole will be slightly smaller than this value, while the CD at the top of the hole will be slightly larger as a result of this conical or triangular shape.

The structure shown in FIG. 2a illustrates the problems associated with the conventional process, namely that a slight misalignment of the photoresist mask can exacerbate the problem of lateral etching causing one of the poly gates 6B to connect 19 with the hole 18. This “bridging” between the poly gate 6B and the contact hole 18 causes undesired electrical connection between adjacent elements that are designed to be electrically isolated, thus resulting in undesired rework or scrap.

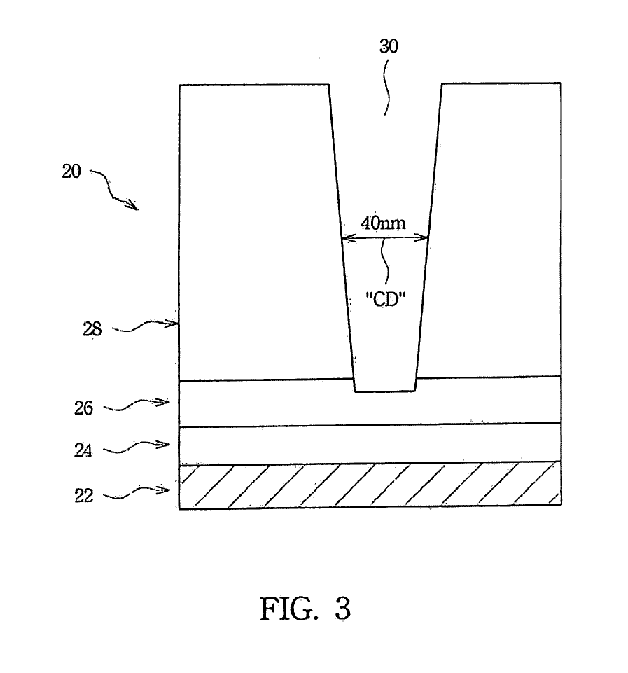

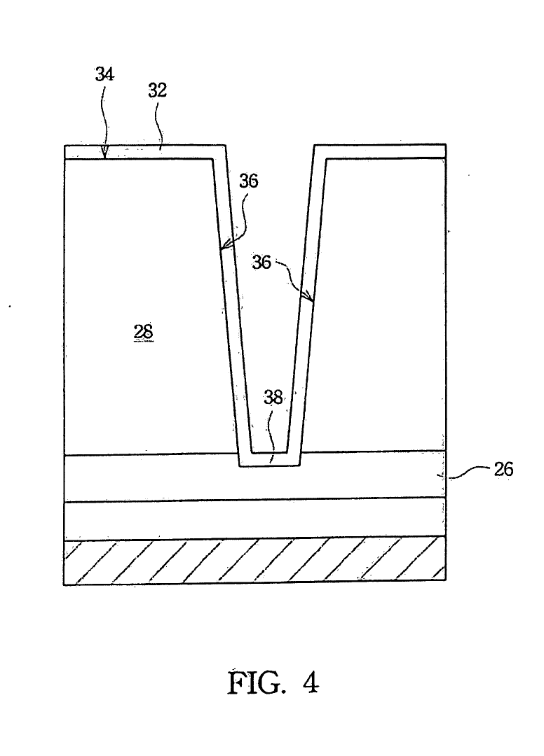

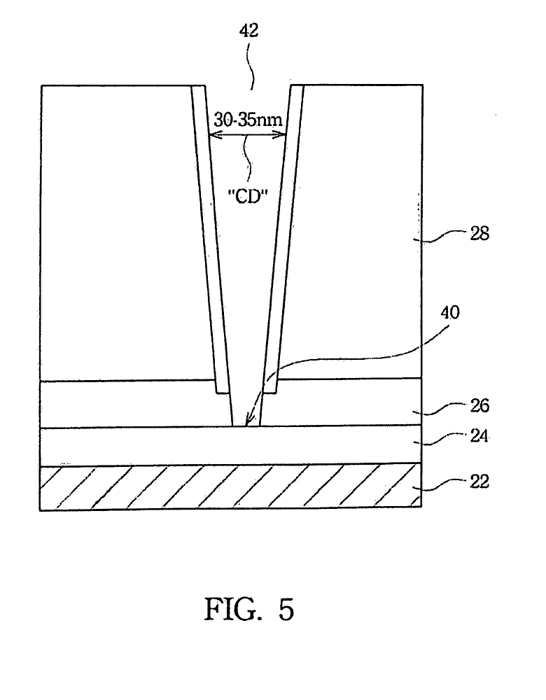

Now referring to FIG. 3, a multilayer stack 20 is shown comprising a substrate layer 22, a conductive material layer 24, an etch stop layer 26, and a layer of interlevel dielectric 28. In one embodiment, the etch stop layer 26 comprises silicon nitride and the interlevel dielectric layer comprises silicon oxide, phosphosilicate glass (PSG), borosilicate glass (BSG), boro-phospho-silicate glass (BPSG), fluoro-silicate glass (FSG) or undoped silicate glass (USG). The conductive material layer 24 may comprise nickel silicide (NiSi), cobalt silicide (CoSi) or titanium silicide (TiSi). A photoresist mask (not shown) may be patterned over the interlevel dielectric layer 28. Additionally, although not shown, one or more layers of ARC and/or DARC material may be disposed between the interlevel dielectric layer 28 and the photoresist mask. Anisotropic etching of the multilayer stack 20 may then proceed according to the pattern of the photoresist mask to form a hole 30 through the layers, ending at or within the etch stop layer 26, thereby protecting the conductive material layer 24 from the etch process. In one exemplary embodiment, the hole 30 may have a critical dimension “CD” of from about 35 nanometers to about 45 nanometers, and in one embodiment may have a CD of about 40 nanometers as measured at or near the top of the adjacent poly gate 6A, 6B.

The conductive material layer 24 may have a thickness of about 150 Angstroms (Å) to about 300 Å. The etch stop layer 26 may have a thickness of about 200 Å to about 400 Å. The interlevel dielectric layer 28 may have a thickness of about 2,000 Å to about 2,500 Å. Where provided, ARC and DARC layers may be provided in thicknesses previously discussed in relation to FIG. 1.

The conductive material layer 24 may be deposited using any of a variety of known techniques, including electroplating, vapor deposition, chemical vapor deposition (CVD), plasma-enhanced chemical vapor deposition (PECVD) or the like. Additionally, appropriate CVD or PECVD techniques may be used to deposit the etch stop layer 26, the interlevel dielectric layer 28, and the ARC and DARC layers. The photoresist layer may be deposited using a spin-on process or a CVD process as desired.

Subsequent to the first etching step, a plasma ashing process may be employed to remove the photoresist, ARC and DARC layers (where used), as well as any residual polymer remaining on the inner surfaces of the hole 30 resulting from the etch process.

An isolation liner layer 32 may then be deposited over the upper surface 34 of the interlevel dielectric layer 28, as well as the sidewall surfaces 36 of the hole 30 and an upper surface 38 of the etch stop layer 26. In this manner the isolation liner layer lines the walls and bottom of the hole 30. The isolation liner layer 32 may be applied by CVD, PECVD, or other appropriate deposition technique to result in a layer thickness of about 50 Å to about 100 Å. In one embodiment, the isolation liner layer 32 is deposited using a high aspect ratio process (HARP), achieving a 5-10 nm shrink. This is beneficial because it results in a smaller CD for the resulting hole 30 due to the shrink in the liner layer thickness upon application.

The material used to form the isolation liner layer 32 may be selected based on its properties in resisting lateral etching of the etchant used to form the hole 30. For example, a HARP film (oxide) may be used due to its good uniformity and step coverage. A non-limiting list of exemplary materials for use as the isolation liner layer 32 comprise non-conductive films such as OX, SiN and SiON.

Once the isolation liner layer 32 has been deposited, an anisotropic etch of the isolation liner layer 32 and the etch stop layer 26 may then be performed to remove the portion of the isolation liner material 32 disposed over the upper surface 34 of the interlevel dielectric layer 28, and to expose an upper surface 40 of the conductive material layer 24, thus forming lined contact hole 42. Advantageously, the anisotropic etch removes the isolation liner material 32 at the bottom of the hole, but does not substantially remove the isolation liner material 32 deposited on the side surfaces of the lined contact hole 42.

The lined contact hole 42 may have a critical dimension “CD” of about 30-35 nm as measured at or near the center of the hole 42, which is smaller than that of the hole 30 formed by the original anisotropic etching step.

It will be appreciated that either an isotropic or anisotropic etch technique can be used to form lined contact hole 42, but an anisotropic etch may be more desirable since it may minimize lateral etching of the isolation liner layer 32 disposed on the hole sidewalls 36. Additionally, the material used to form the isolation liner layer 32 may be selected to minimize lateral etching in response to the application of a particular anisotropic etchant gas or gas combination.

It will be appreciated that the addition of isolation liner layer 32 to the sidewalls 36 results in a greater lateral thickness of insulating material between adjacent conductive structures, thus reducing the chance for undesirable bridging caused by mis-positioning of the photomask combined with aggressive lateral etching.

An additional advantage is that the material used to form the isolation liner layer 32 may have superior insulating characteristics as compared to the surrounding interlevel dielectric material layer 28, further inhibiting bridging between adjacent conductive structures. Finally, the isolation liner layer 32 provides a contact hole with a smaller critical dimension “CD” than that formed by conventional processes, and also reduces the aspect ratio of the contact hole.

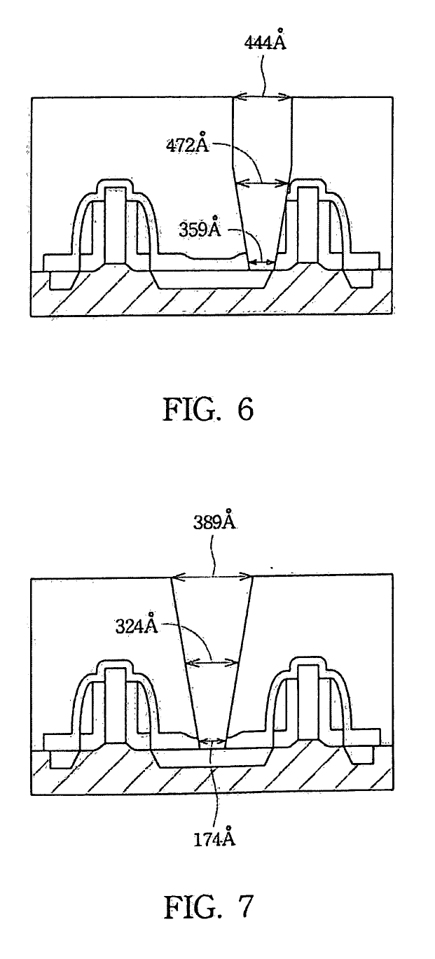

Referring now to FIGS. 6 and 7, cross-sectional views of finished contact hole structures are shown. Specifically, FIG. 6 shows a contact hole formed using a conventional process in which the hole (again, with a roughly triangular cross-sectional shape) has a cross-sectional dimension of 359 Å at its bottom, about 472 Å at its midpoint, and about 444 Å at the top. FIG. 7 shows a contact hole formed using the disclosed process in which the hole has a cross-sectional dimension of 174 Å at its bottom, about 324 Å at its midpoint, and about 389 Å at the top.

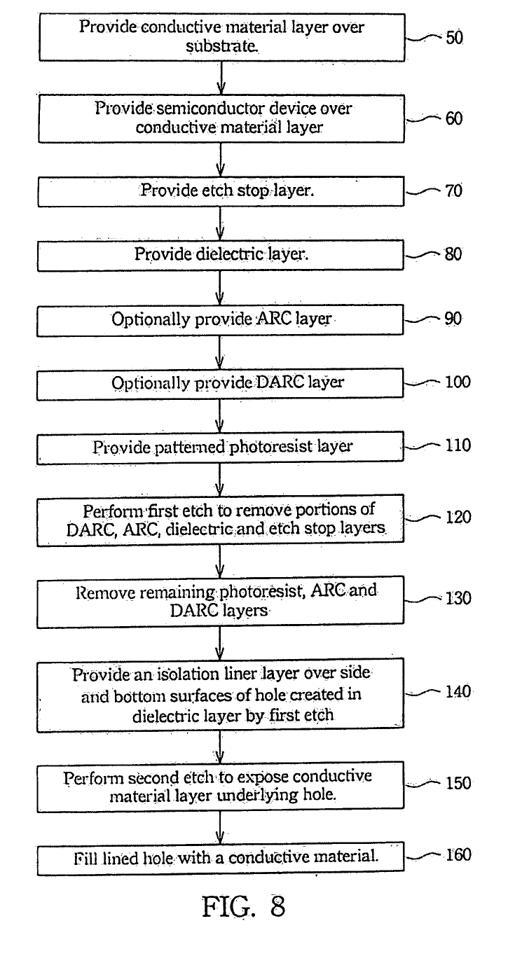

An exemplary process of forming a contact hole 18 will now be described in relation to FIG. 8. At step 50 a layer of conductive material 24 is formed over a substrate layer. At step 60, a device is formed over the conductive material layer 24 in one or more discrete steps. At step 70, an etch stop layer 26 is provided over the device and conductive material layer. At step 80, an dielectric layer 28 is deposited over the etch stop layer 26. At steps 90 and 100, optional ARC and DARC layers are deposited over the dielectric layer 28. At step 110, a patterned photoresist layer is provided over the DARC layer. If no ARC or DARC layer is used, the patterned photoresist layer is provided over the dielectric layer.

At step 120, a first etch step is performed to remove portions of the layers 26, 28 left unprotected by the predetermined pattern in the photoresist layer, thus forming a hole 30 through layer 28 and through a portion of layer 26. At step 130, the photoresist layer, and optional ARC and DARC layers are removed using an ashing process. At step 140, an isolation liner layer 32 is deposited over an upper surface of the dielectric layer 28 as well as the inner side and bottom surfaces 36 of the hole 30. In one embodiment, this is done using a high aspect ratio process and achieves a thickness shrink of about 5-10 nm. At step 150, a second anisotropic etch step is performed to remove the portion of the isolation liner layer 32 overlying the upper surface 38 of the first dielectric layer 26, and to expose the portion of the conductive material layer 24 underlying the hole 30. At step 160, the lined hole 42 is filled with a conductive material such as copper or the like.

### ADVANTAGES OF THE INVENTION

The inventive process is simple and thus can be implemented at low cost. Further, due to the appropriate selection of the material used to form the isolation liner layer, lateral etching can be substantially eliminated, which can substantially eliminate the chance for undesirable bridging defects.

While the foregoing invention has been described with reference to the above embodiments, various modifications and changes can be made without departing from the spirit of the invention. Accordingly, all such modifications and changes are considered to be within the scope and range of equivalents of the appended claims.

1. A method of forming a hole in a multi-layer stack, comprising the steps of:
(a) providing a substrate layer;
(b) providing a layer of conductive material over the substrate layer;
(c) providing an etch stop layer over said conductive material layer;
(d) providing a dielectric layer over the etch stop layer;
(e) providing a photoresist layer over the dielectric layer, the photoresist layer have a predetermined pattern;
(f) performing a first etch to remove portions of the layers unprotected by the predetermined pattern, thereby forming a hole through the dielectric layer and a portion of the etch stop layer defined by the predetermined pattern;
(g) removing the photoresist layer;
(h) providing an isolation liner layer over an upper surface of the interlevel dielectric layer, the isolation liner layer further covering inner side surfaces of the hole etched through the interlevel dielectric layer and an upper surface of the etch stop layer exposed by the first etch; and
(i) performing a second etch to remove the portion of the isolation liner layer overlying the upper surface of the first dielectric layer exposed by the first etch;
wherein the second etch exposes a portion of the conductive material layer.

2. The method of claim 1, wherein the isolation liner layer is deposited using a high aspect ratio process (HARP), achieving a 5-10 nm shrink in thickness.

3. The method of claim 2, wherein the first and second etch steps comprise anisotropic etch steps.

4. The method of claim 2, further comprising filling the hole with conductive material.

5. The method of claim 1, further comprising the steps of:
providing an antireflective coating (ARC) layer over the dielectric layer; and
providing a dielectric antireflective coating (DARC) layer over the first ARC layer;
wherein the steps of providing an ARC layer and providing a DARC layer are performed prior to the step of providing a photoresist layer.

6. The method of claim 1, wherein the conductive material layer comprises Nickel Silicide.

7. The method of claim 6, wherein the isolation liner layer comprises a material selected from the list consisting of oxide, silicon nitride, and silicon oxynitride.

8. A method for forming a contact hole or via, comprising the steps of:
(a) providing a substrate;
(b) providing a layer of conductive material over the substrate;
(c) providing a semiconductor device over the conductive material layer;
(d) providing a multilayer stack comprising a plurality of dielectric layers;
(e) providing a patterned photoresist layer over the multilayer stack;
(f) performing a first etch to remove portions of the plurality of layers unprotected by the photoresist layer, the first etch forming a hole through the plurality of layers and ending on or within a first dielectric layer of said multilayer stack, said first dielectric layer directly overlying said conductive material layer;
(g) removing the patterned photoresist layer and all but two of the plurality of dielectric layers to leave the first dielectric layer, a second dielectric layer, and the hole formed through the first and second dielectric layers;
(h) providing an isolation liner layer over an upper surface of the second dielectric layer, the isolation liner layer further covering inner side surfaces of the hole and an upper surface of the first dielectric layer exposed by the first etch; and
(i) performing a second etch to remove the portion of the isolation liner layer overlying the upper surface of the first dielectric layer exposed by the first etch;
wherein the second etch exposes a portion of the conductive material layer.

9. The method of claim 8, wherein the isolation liner layer is deposited using a high aspect ratio process (HARP), achieving a 5-10 nm shrink in thickness.

10. The method of claim 9, wherein first dielectric layer directly overlying said conductive material layer comprises an etch stop layer.

11. The method of claim 10, wherein each of the first and second etch steps comprises an anisotropic etch.

12. The method of claim 8, further comprising filling the hole with conductive material.

13. The method of claim 8, wherein the conductive material layer comprises Nickel Silicide.

14. The method of claim 8, wherein the isolation liner layer comprises a material selected from the list consisting of oxide, silicon nitride, and silicon oxynitride.

15. An etching method, comprising the steps of:
(a) providing a layer of conductive material over a substrate;
(b) providing an etch stop layer over the active device and the conductive material layer;
(c) providing a plurality of dielectric layers over the etch stop layer;
(d) providing a patterned photoresist layer over the plurality of dielectric layers;
(e) performing a first etch to remove portions of the plurality of layers unprotected by the photoresist layer, the first etch forming a hole through the plurality of layers and ending at or within the etch stop layer;
(f) removing the patterned photoresist layer as well as any layers overlying a first dielectric layer of the plurality of dielectric layers and the etch stop layer;
(g) providing an isolation liner layer over an upper surface of the first of the plurality of dielectric layers, the isolation liner layer further covering inner side surfaces of the hole and an upper surface of the etch stop layer exposed by the first etch; and
(h) performing a second etch to remove the portion of the isolation liner layer overlying the upper surface of the etch stop layer exposed by the first etch;
wherein the second etch exposes a portion of the conductive material layer.

16. The method of claim 15, wherein the isolation liner layer is deposited using a high aspect ratio process (HARP), achieving a 5-10 nm shrink in thickness.

17. The method of claim 16, wherein each of the first and second etch steps comprises an anisotropic etch.

18. The method of claim 17, wherein the conductive material layer comprises Nickel Silicide.

19. The method of claim 18, wherein the isolation liner layer comprises a material selected from the list consisting of oxide, silicon nitride, and silicon oxynitride.

20. The method of claim 15, further comprising filling the hole with conductive material.
